(19) United States
(12) Patent Application Publication
(10) Pub. No.: US 2016/0128186 A1
(43) Pub. Date: May 5, 2016

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Suk Hyeon CHO, Suwon-Si (KR); Yong Ho BAEK, Suwon-Si (KR); Young Gwan KO, Suwon-Si (KR); Yoong OH, Suwon-Si (KR); Young Kuk KO, Suwon-Si (KR)

(21) Appl. No.: 14/857,817

(22) Filed: Sep. 17, 2015

(30) Foreign Application Priority Data
Nov. 5, 2014 (KR) 10-2014-0153186

(51) Int. Cl. H05K 1/03; H05K 3/10; H05K 3/00; H05K 1/11

(52) U.S. Cl. CPC H05K 1/0306; H05K 1/032; H05K 1/115; H05K 3/10; H05K 3/0011

(57) ABSTRACT

A printed circuit board includes a core part including a glass plate and resin layers disposed on an upper surface and a lower surface of the glass plate, and a wiring layer disposed on at least one of an upper portion and a lower portion of the core part. The core part includes a groove part penetrating from the upper surface to the lower surface of the glass plate while being spaced apart from a side surface of the core part by a predetermined distance.

### CROSS-REFERENCE TO RELATED APPLICATION

This application claims the priority and benefit of Korean Patent Application No. 10-2014-0153186 filed on Nov. 5, 2014, with the Korean Intellectual Property Office, the disclosure of which is incorporated herein by reference.

### BACKGROUND

The present disclosure relates to a printed circuit board and a method of manufacturing the same.

As printed circuit boards have become gradually thinner over time, degrees of deformities such as warpage, torsion, or the like occurring when printed circuit boards are manufactured have increased. In order to prevent such deformities, a glass core structure in which a glass plate is embedded in a core part of a printed circuit board has been suggested.

### SUMMARY

An aspect of the present disclosure may provide a printed circuit board able to prevent a crack in a glass plate occurring when the glass plate is cut from propagating to an inner portion of the glass plate.

According to an aspect of the present disclosure, a printed circuit board may include a core part including a glass plate and resin layers disposed on an upper surface and a lower surface of the glass plate, and a wiring layer disposed on at least one of an upper portion and a lower portion of the core part, wherein a groove part penetrating through the glass plate so as to separate a side surface and an inner portion of the glass plate from each other may be continuously formed.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1A and 1B are cross-sectional views illustrating a structure of a printed circuit board according to an exemplary embodiment in the present disclosure;

FIGS. 2 through 4 are cross-sectional views illustrating a structure of a printed circuit board according to other exemplary embodiments in the present disclosure;

FIGS. 5A through 5D are views illustrating a process of manufacturing a core part of a printed circuit board according to an exemplary embodiment; and

FIGS. 6A through 6F are views sequentially illustrating a process of manufacturing a printed circuit board according to an exemplary embodiment.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Printed Circuit Board

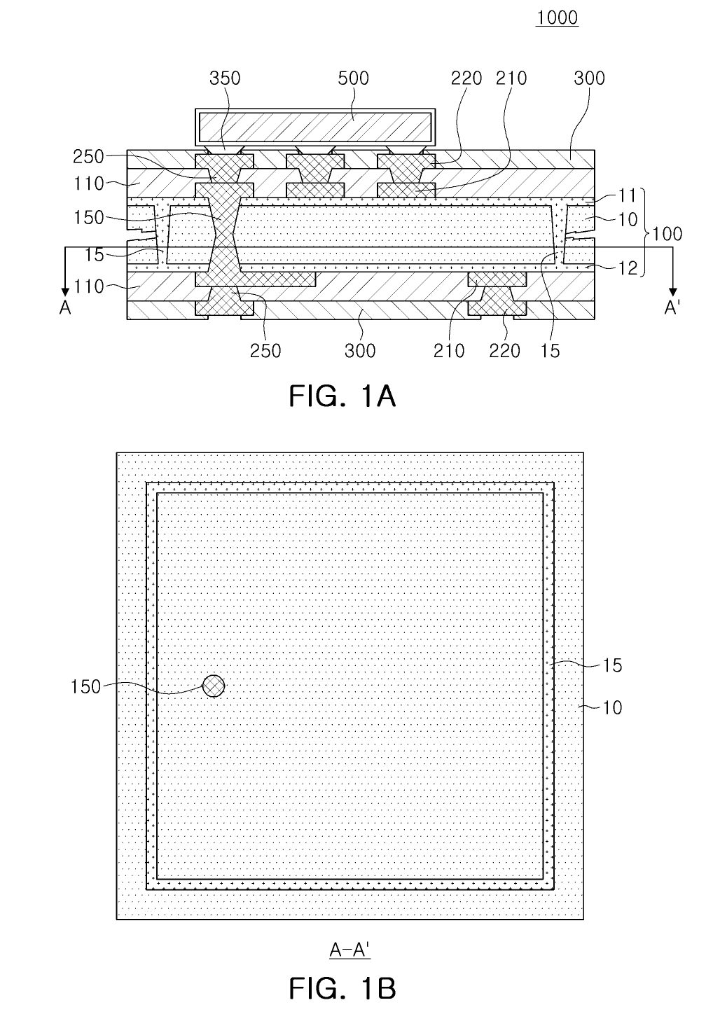

FIG. 1A is a side cross-sectional view illustrating a structure of a printed circuit board according to an exemplary embodiment in the present disclosure, and FIG. 1B is a cross-sectional view taken along line A-A′ of FIG. 1A.

Referring to FIGS. 1A and 1B, a printed circuit board 1000 according to an exemplary embodiment may include a core part 100 including a glass plate 10 and resin layers 11 and 12 disposed on an upper surface and a lower surface of the glass plate 10. The core part 100 may include a groove part 15 penetrating from the upper surface of the glass plate 10 to the lower surface thereof, while being spaced apart from a side surface of the core part 100 by a predetermined distance. The groove part 15 may be continuously formed to separate a side surface and an inner portion of the glass plate 10.

The glass plate 10 may be exposed to the side surface of the core part 100. The printed circuit board 1000 according to an exemplary embodiment in the present disclosure may have the groove part 15 formed to be spaced apart from the exposed surface of the glass plate 10, that is, the side surface of the core part 100, by the predetermined distance.

The glass plate 10 may include glass, which is an amorphous solid.

The material used for the glass in the exemplary embodiment in the present disclosure may include, for example, pure silicon dioxide (SiO₂ of about 100%), soda lime glass, borosilicate glass, alumino-silicate glass, or the like. However, the glass material is not limited to silicon-based glass. For example, alternative glass materials such as fluoride glass, phosphate glass, chalcogen glass, or the like may also be used.

In addition, in order to form glass having a certain physical characteristic, other additives may further be included. The additives may include magnesium (Mg), calcium (Ca), manganese (Mn), aluminum (Al), lead (Pb), boron (B), iron (Fe), chromium (Cr), potassium (K), sulfur (S), and/or antimony (Sb), as well as calcium carbonate (e.g., lime) and/or sodium carbonate (e.g., soda), and a carbonate and/or oxide of the above-mentioned elements and other elements.

During a manufacturing process in which the glass plate is cut to be included in a printed circuit board unit, a crack may occur on a cut area of the glass plate, and the crack may propagate to the inner portion of the glass plate.

According to an exemplary embodiment, the groove part 15 may be formed to be spaced apart from the exposed surface of the glass plate 10, that is, the side surface of the core part 100, by a predetermined distance, such that a crack occurring in the glass plate when the glass plate is cut may be prevented from propagating to the inner portion of the glass plate.

The groove part 15 may be filled with a resin.

The resin may be a thermosetting resin such as an epoxy resin, a thermoplastic resin such as polyimide, or the like.

The resin filling the groove part 15 may be integrated with a resin forming the resin layers 11 and 12.

Since the resin layers 11 and 12 may be formed on the upper surface and the lower surface of the glass plate 10, and simultaneously, the groove part 15 may be filled with the resin forming the resin layers 11 and 12, the resin filling the groove part 15 may be integrated with the resin forming the resin layers 11 and 12.

The resin layers 11 and 12 may include a thermosetting resin such as an epoxy resin or a thermoplastic resin such as polyimide. In addition, a fabric reinforcement material such as glass fabric may be impregnated in the aforementioned resin to form, for example, pre-preg.

The groove part 15 may be formed along the side surface of the core part 100 while being spaced apart from the side surface of the core part 100 by a predetermined distance.

The groove part 15 may be formed along the side surface of the core part 100 while being spaced apart from the side surface of the core part 100 by the predetermined distance, such that a crack occurring on the exposed surface of the glass plate, that is, the side surface of the core part 100, when the glass plate is cut may be prevented from propagating to the inner portion of the glass plate.

In another exemplary embodiment in which the side surface of the glass plate may be covered by a resin so that the glass plate is not externally exposed, and thus, a crack may not occur on the glass plate when the glass plate is cut, the groove part may need to be formed to have a relatively wider width in consideration that the resin may be scattered. Thus, an entire groove part may not be filled with a thin resin layer covering the glass plate, and thus, a void may occur.

However, according to an exemplary embodiment in the present disclosure, although the groove part 15 is formed to have a relatively narrow width, a crack occurring on the exposed surface of the glass plate may be prevented from propagating to the inner portion of the glass plate. In addition, since the groove part 15 is formed to have a relatively narrow width, the groove part 15 may be filled only with the thin resin layer covering the glass plate, and the groove part 15 may be relatively well filled with the resin. In addition, since the groove part 15 is formed to have a narrow width, a relatively small area of the glass plate is removed to form the groove part, such that time consumed to process the glass plate may be reduced, manufacturing costs may be decreased, and stability of a panel during a manufacturing process may be excellent.

The groove part 15 may be disposed along four side surfaces of the core part 100.

A crack may occur on a cut area of the glass plate when the glass plate is cut into printed circuit board units. However, the crack may be prevented from propagating to the inner portion of the glass plate by forming the groove part 15 along the four side surfaces, the cut area, of the core part 100.

Wiring layers 210 and 220 and an insulating layer 110 may be disposed on upper and lower portions of the core part 100.

The insulating layer 110 may be formed of a thermosetting resin such as an epoxy resin, or a thermoplastic resin such as polyimide. In addition, a reinforcement material such as glass fiber or inorganic filler impregnated in the aforementioned resin, such as pre-preg, may be used to form the insulating layer 110.

A material of the wiring layers 210 and 220 may be used without limitation as long as the material is a conductive metal. For example, copper (Cu) may be used.

A first wiring layer 210 disposed on one surface of the core part 100 and another first wiring layer 210 disposed on the other surface of the core part 100 opposing the one surface of the core part 100 may be connected to each other by a via 150 penetrating through the core part 100.

In addition, the first wiring layer 210 disposed on the one surface of the core part 100 and a second wiring layer 220 disposed on one surface of the insulating layer 110 may be connected to each other by a via 250 penetrating through the insulating layer 110.

The vias 150 and 250 may be formed of the same material as the material forming the wiring layers 210 and 220. For example, copper (Cu) may be used, but the material of the vias 150 and 250 is not limited thereto, and any material may be used without limitation as long as it is a conductive metal.

In this case, although one build-up layer is stacked on the upper and lower portions of the core part 100 in FIG. 1A, the number of build-up layers stacked on the upper and lower portions of the core part 100 is not limited thereto, and two or more build-up layers may be disposed on one surface of the core part 100.

A solder resist 300 may be disposed on a surface of the printed circuit board 1000 so that a wiring pattern for an external terminal connection pad is exposed from the second wiring layer 220, which is the outermost wiring layer.

A solder bump 350 may be disposed on the exposed wiring pattern for the external terminal connection pad, and a semiconductor chip 500 may be mounted on the solder bump 350.

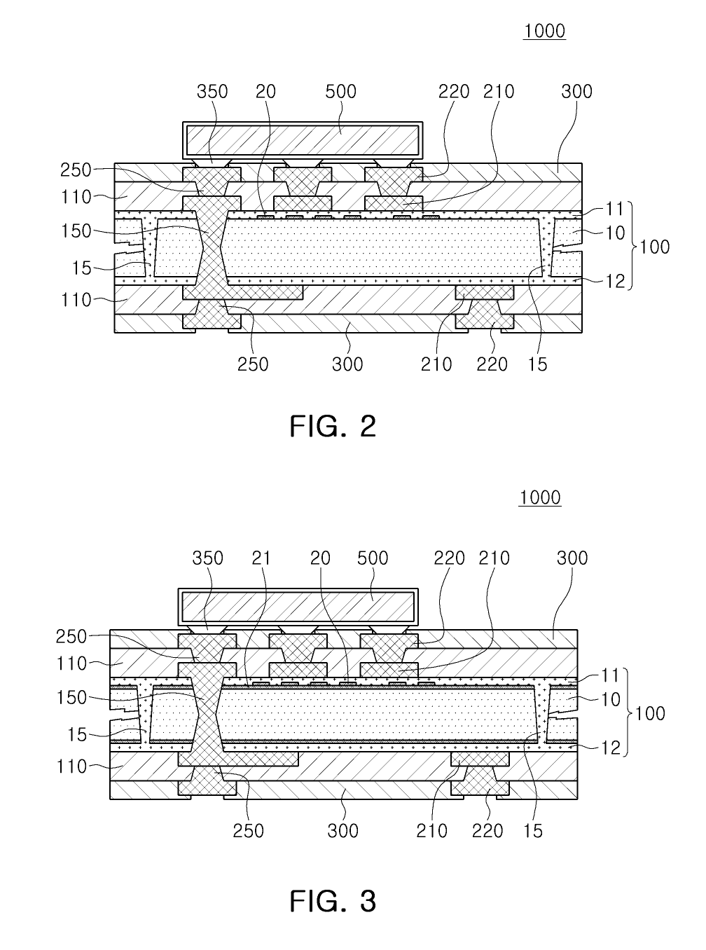

FIGS. 2 through 4 are cross-sectional views illustrating a structure of a printed circuit board according to other exemplary embodiments in the present disclosure.

Referring to FIG. 2, a printed circuit board 1000, according to another exemplary embodiment in the present disclosure, may further include an internal circuit layer 20 disposed on a glass plate 10.

The internal circuit layer 20 may be implemented by a wiring pattern, an inductor, a capacitor, a resistor, or the like. The internal circuit layer 20 may be connected to a wiring layer 210 disposed on one surface of a core part 100 through a via (not illustrated).

With the exception of the internal circuit layer 20, configurations overlapping with the configurations of the printed circuit board according to an exemplary embodiment described above may be equally applied.

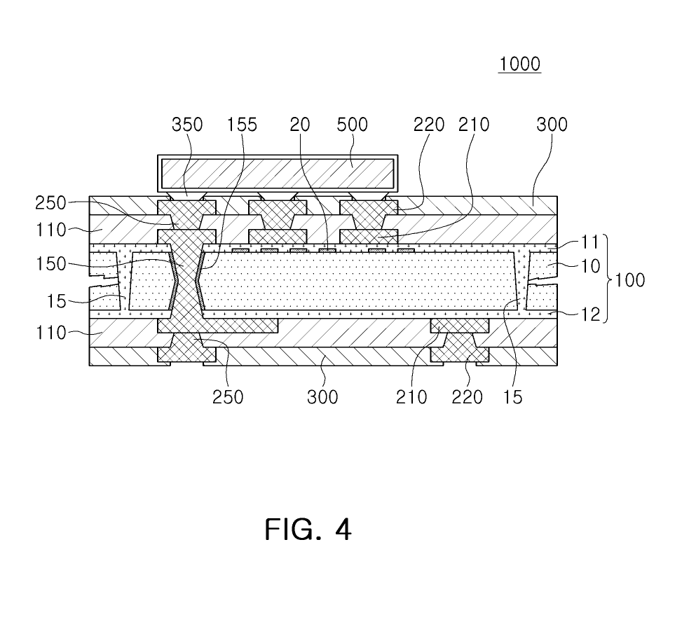

Referring to FIG. 3, a printed circuit board 1000 according to another exemplary embodiment in the present disclosure may further include an adhesive layer 21 disposed between a glass plate 10 and an internal circuit layer 20.

The adhesive layer 21 may be provided to improve adhesion between the glass plate 10 and the internal circuit layer 20. Any layer may be used without limitation as long as it improves adhesion between the glass plate 10 and the internal circuit layer 20. For example, a resin layer such as an epoxy resin layer may be used.

With the exception of the adhesive layer 21, configurations overlapping with the configurations of the printed circuit board according to an exemplary embodiment described above may be equally applied.

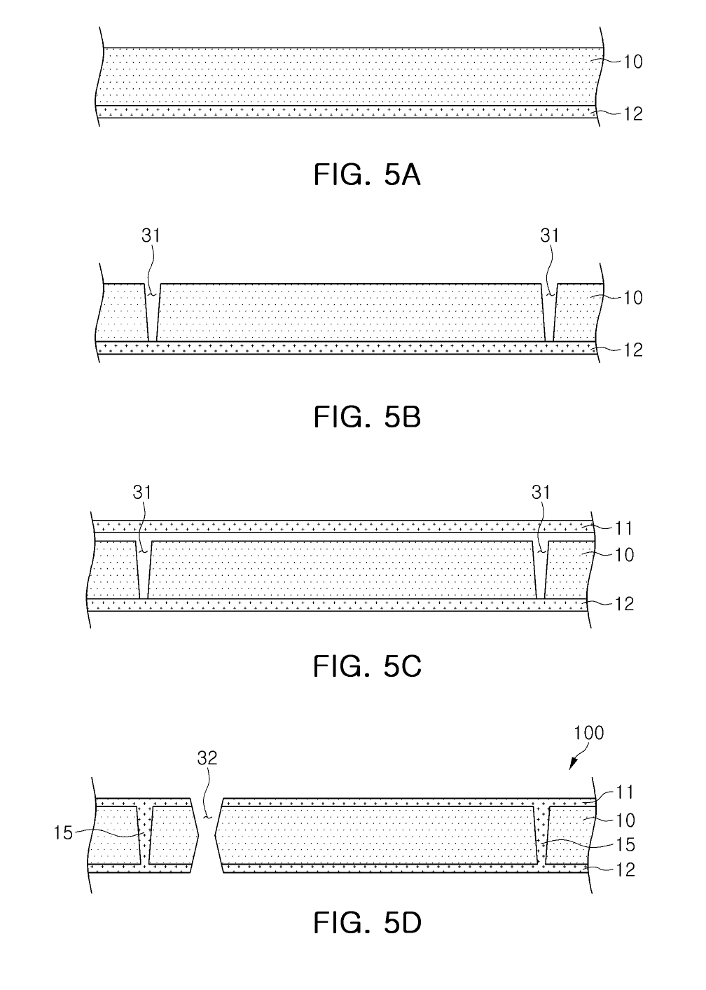

Referring to FIG. 4, a printed circuit board 1000 according to another exemplary embodiment in the present disclosure may further include a protection layer 155 disposed between a via 150 penetrating through a core part 100 and a glass plate 10.

The protection layer 155 may be provided to alleviate a difference in thermal expansion coefficients of the glass plate 10 and the via 150. Any layer that may alleviate the difference in the thermal expansion coefficients of the glass plate 10 and the via 150 may be used without limitation. For example, a metal layer such as titanium (Ti) layer or a resin layer such as an epoxy resin layer may be used.

With the exception of the protection layer 155, configurations overlapping with the configurations of the printed circuit board according to an exemplary embodiment described above may be equally applied.

### Method of Manufacturing Printed Circuit Board

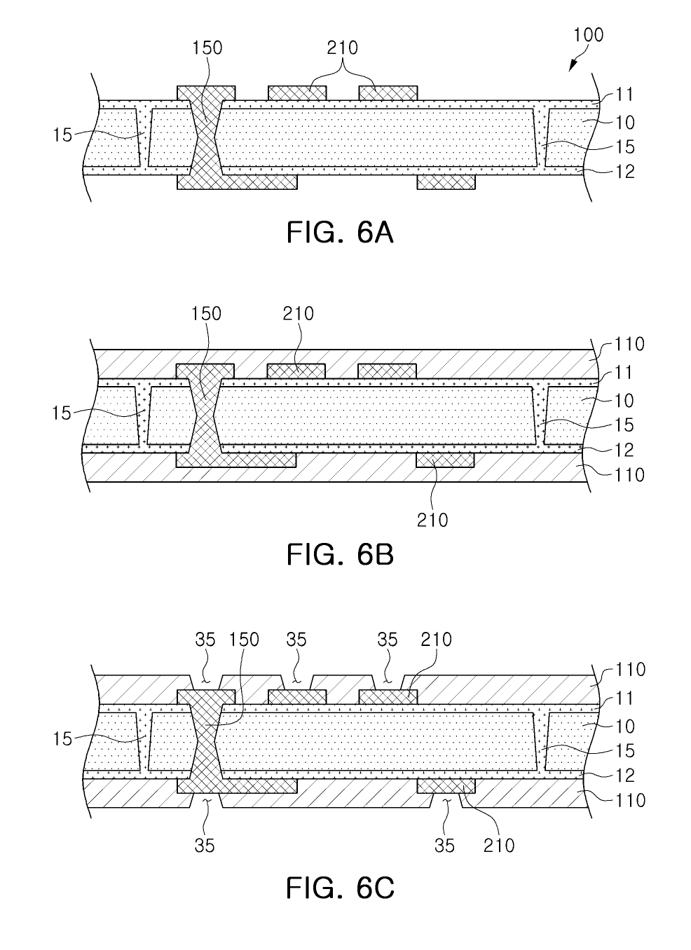

FIGS. 5A through 5D are views illustrating a process of manufacturing a core part of a printed circuit board according to an exemplary embodiment in the present disclosure.

Referring to FIG. 5A, a glass plate 10 may first be stacked on a resin layer 12.

The glass plate 10 may include pure silicon dioxide (SiO₂ of about 100%), soda lime glass, borosilicate glass, alumino-silicate glass, or the like, and a material of the glass plate 100 is not limited to silicon-based glass. For example, alternative glass materials such as fluoride glass, phosphate glass, chalcogen glass, or the like may also be used.

Areas of a plurality of printed circuit board units on the glass plate 10 may be set, and an area to be cut when the glass plate 10 is cut into the respective printed circuit board units may be set to be between the areas of the plurality of printed circuit board units on the glass plate 10.

Referring to FIG. 5B, a groove part hole 31 penetrating from an upper surface of the glass plate 10 to a lower surface thereof while being spaced apart from the cut area by a predetermined distance may be formed.

The groove part hole 31 may be continuously formed along the cut area of the glass plate 10 while being spaced apart from the cut area of the glass plate 10 by the predetermined distance.

A crack may occur on the cut area of the glass plate 10 during the manufacturing process in which the glass plate is cut into the printed circuit board units. Thus, the groove part hole 31 may be formed along the cut area of the glass plate 10 in order to prevent the crack from propagating to an inner portion of the glass plate 10 when the glass plate 10 is cut.

The groove part hole 31 may be formed using a mechanical drill, a laser drill, sandblasting, a chemical etching, or the like, but is not particularly limited thereto.

Referring to FIG. 5C, a resin layer 11 may be formed on the upper surface of the glass plate 10.

The resin layer 11 may be formed of a thermosetting resin such as an epoxy resin or a thermoplastic resin such as polyimide. In addition, a fabric reinforcement material such as glass fabric may be impregnated in the aforementioned resin to form, for example, pre-preg.

Referring to FIG. 5D, the core part 10 may be formed by forming the resin layer 11 on the upper surface of the glass plate 10 and then heating and compressing the resin layer 11 to stack the resin layer 11 thereon, and a groove part 15 may be simultaneously formed as the resin forming the resin layer 11 may fill in the groove part hole 31.

Since the resin layer 11 may be stacked on the upper surface of the glass plate 10, and simultaneously, the groove part hole 31 may be filled with the resin forming the resin layer 11, the resin forming the groove part 15 may be integrated with the resin forming the resin layer 11.

According to an exemplary embodiment in the present disclosure, although the groove part 15 is formed to have a relatively small width, a crack occurring on the cut area of the glass plate may be prevented from propagating to the inner portion of the glass plate. In addition, since the groove part 15 is formed to have a relatively small width, the groove part may be filled only with the resin of the thin resin layer covering the glass plate, and the groove part 15 may be relatively well filled with the resin. Further, since the groove part 15 may be formed to have a relatively small width, a relatively small area of the glass plate may be removed to form the groove part 15, such that time required to process the glass plate may be reduced, manufacturing costs may be decreased, and panel stability in a manufacturing process may be excellent.

After the resin layer 11 is stacked, a via hole 32 penetrating through the core part 100 may be formed in the core part 100.

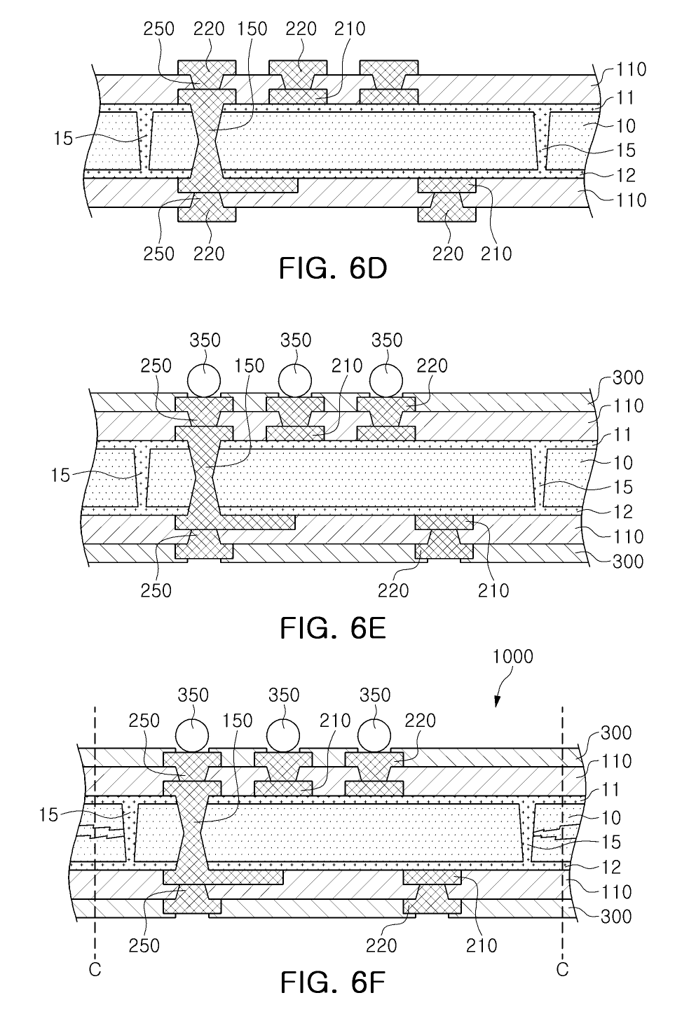

FIGS. 6A through 6F are views sequentially illustrating a process of manufacturing a printed circuit board according to an exemplary embodiment in the present disclosure.

Referring to FIG. 6A, a via 150 may be formed by filling a via hole 32 with a conductive metal, and first wiring layers 210 connected to each other by the via 150 may be formed on one surface and the other surface of the core part 100.

Filling with the conductive metal and forming the first wiring layers 210 may, for example, be performed by using a process such as a plating process, and any metal having excellent electric conductivity may be used for the conductive metal without limitation. For example, copper (Cu) may be used.

Referring to FIG. 6B, an insulating layer 110 may be formed on the first wiring layers 210.

The insulating layer 110 may be formed of a thermosetting resin such as an epoxy resin, or a thermoplastic resin such as polyimide. In addition, a reinforcement material such as glass fiber or inorganic filler impregnated in the aforementioned resin, such as pre-preg, may be used to form the insulating layer 110.

Referring to FIG. 6C, a via hole 35 penetrating through the insulating layer 110 may be formed in the insulating layer 110.

The via hole 35 may be formed using a mechanical drill, a laser drill, sandblasting, or the like, but is not particularly limited thereto.

Referring to FIG. 6D, a via 250 may be formed by filling the via hole 35 with a conductive metal, and second wiring layers 220 connected to the first wiring layers 210 by the via 250 may be formed on the insulating layer 110.

Filling with the conductive metal and forming the second wiring layers 220 may be, for example, performed by using a process such as a plating process, and any metal having excellent electric conductivity may be used for the conductive metal without limitation. For example, copper (Cu) may be used.

Two or more build-up layers (not illustrated) may be formed on one surface of the core part 100 by repeating the process of forming the via 250 and the second wiring layers 220.

Referring to FIG. 6E, a solder resist 300 may be formed so that a wiring pattern for the external terminal connection pad is exposed from the second wiring layers 220, which is the outermost wiring layer, and the solder bump 350 able to have a semiconductor chip thereon may be formed on the exposed wiring pattern for the external terminal connection pad.

Referring to FIG. 6F, a printed circuit board unit 1000 may be formed by cutting the manufactured stacked substrate along a cut area C.

In this case, the glass plate 10 may be cut and the glass plate 10 may be exposed to a side surface of the core part 100.

A crack occurring on the cut area C, that is, the exposed surface of the glass plate 10 during the manufacturing process of cutting the glass plate 10 into the printed circuit board units may propagate to the inner portion of the glass plate. According to an exemplary embodiment in the present disclosure, the crack occurring when the glass plate 10 is cut may be prevented from propagating to the inner portion of the glass plate 10, by forming the groove part 15 spaced apart from the exposed surface of the glass plate 10 by a predetermined distance.

Since other features are the same as those of the printed circuit board according to an exemplary embodiment described above, a description thereof will be omitted.

As set forth above, according to exemplary embodiments in the present disclosure, the printed circuit board may prevent cracking when the glass plate is cut from moving into the glass plate.

While exemplary embodiments have been shown and described above, it will be apparent to those skilled in the art that modifications and variations could be made without departing from the scope of the present invention as defined by the appended claims.

1. A printed circuit board comprising:
a core part comprising a glass core and a resin layer disposed on an upper surface and a lower surface of the glass core; and
a wiring layer disposed on the core part,
wherein a groove part is formed in the glass core, the groove part penetrating the glass core between one surface and the other surface of the glass core.

2. The printed circuit board of claim 1, wherein the glass core is separated into an inner portion thereof and an outer portion thereof by the groove part.

3. The printed circuit board of claim 1, wherein the groove part is formed along a side surface of the core part.

4. The printed circuit board of claim 1, wherein the groove part is continuously formed.

5. The printed circuit board of claim 1, wherein the groove part is filled with a resin.

6. The printed circuit board of claim 5, wherein the resin filling the groove part is integrated with a resin forming the resin layer.

7. The printed circuit board of claim 1, wherein a side surface of the glass core is exposed to an outside.

8. The printed circuit board of claim 1, further comprising an internal circuit layer disposed on the glass core.

9. The printed circuit board of claim 8, further comprising an adhesive layer interposed between the glass core and the internal circuit layer
a protection layer disposed between the glass plate and the via.

10. The printed circuit board of claim 1, further comprising:
a via penetrating through the glass core; and
interposed between the glass core and the via.

11. A method of manufacturing a printed circuit board, comprising:
forming a first resin layer on one surface of a glass core;
forming a groove part hole penetrating the glass core;
forming a core part by forming a second resin layer on the other surface of the glass core;
forming a wiring layer on the core part; and
a cut area located at an outside of the groove part hole.

12. The method of manufacturing a printed circuit board of claim 11, further comprising filling the groove part hole with a resin
forming a printed circuit board unit by cutting the core part along the cut area.

13. The method of manufacturing a printed circuit board of claim 12, wherein the filling of the groove part hole with the resin, the groove part hole is filled with the resin of the second resin layer by stacking the second resin layer on the other surface of the glass core.

14. The method of manufacturing a printed circuit board of claim 11, wherein in the forming of the printed circuit board unit, a side surface of the glass core is exposed to an outside.

15. The method of manufacturing a printed circuit board of claim 11, wherein in the forming of the groove part hole, the groove part hole is continuously formed along the cut area.

16. (canceled)
